(19) United States
(12) Patent Application Publication
(10) Pub. No.: US 2011/0156268 A1
(43) Pub. Date: Jun. 30, 2011

(54) Semiconductor Process, Semiconductor Element and Package Having Semiconductor Element

(76) Inventor: Bin-Hong Cheng, Kaohsiung (TW)

(21) Appl. No.: 12/818,720

(22) Filed: Jun. 18, 2010

(30) Foreign Application Priority Data
Dec. 29, 2009 (TW) 098145580

(51) Int. Cl. H01L 23/48; H01L 21/311

(52) U.S. Cl. 257/774; 438/703; 257/E21.249; 257/E23.011

(57) ABSTRACT

The present invention relates to a semiconductor process, a semiconductor element and a package having a semiconductor element. The semiconductor process includes the following steps: (a) providing a semiconductor element including a silicon base material and at least one conductive via structure disposed in the silicon base material; (b) removing part of the silicon base material to form a first surface, wherein the conductive via structure protrudes from the first surface of the silicon base material so as to form a through via structure; (c) forming a protective layer on the first surface of the silicon base material to cover the through via structure, wherein the protective layer is made of photo-sensitive material; (d) removing part of the protective layer to form a first surface, so as to expose the through via structure on the first surface of the protective layer. Whereby, the protective layer disposed on the through via structure is totally removed, so that the yield rate of electrically connecting the through via structure and external elements is ensured.

### BACKGROUND OF THE INVENTION

1. Field of the Invention

The present invention relates to a semiconductor process, a semiconductor element and package having the semiconductor element, and more particularly, to a semiconductor process, a semiconductor element and package having the semiconductor element that has the through via structure.

2. Description of the Related Art

FIG. 1 shows a cross-sectional view of a conventional semiconductor element. FIG. 2 shows a partial enlarged view of FIG. 1. As shown in FIG. 1 and FIG. 2, the conventional semiconductor element 1 comprises a silicon base material 11, at least one electrical device 12, at least one through via structure 13, a passivation layer 14 and a redistribution layer 15. The silicon base material 11 has a first surface 111, a second surface 112 and at least one groove 113. The groove 113 opens at the first surface 111.

The electrical device 12 is disposed in the silicon base material 11 and exposed on the second surface 112 of the silicon base material 11. The through via structure 13 is disposed in the groove 113. The through via structure 13 has a first end 131 and a second end 132, wherein the first end 131 is exposed on the first surface 111 of the silicon base material 11, and the second end 132 is connected to the electrical device 12. The passivation layer 14 is located on the first surface 111 of the silicon base material 11 and has a surface 141 and at least one opening 142. The opening 142 exposes the first end 131 of the through via structure 13. The redistribution layer 15 is disposed on the surface 141 of the passivation layer 12 and at the opening 142. The redistribution layer 15 comprises at least on electrically-connected region 151 which is connected to the first end 131 of the through via structure 13.

The conventional semiconductor element 1 has following defects. Since the opening 142 of the passivation layer 14 is formed by dry etching which uses plasma to impact the surface to be etched. When the passivation layer 14 is gradually removed and the first end 131 of the through via structure 13 is being exposed, charge accumulates gradually on the first end 131 of the through via structure 13, thus repelling the plasma. Therefore, the plasma reduces the impact on the first end 131 of the through via structure 13, so that the passivation layer 14 on the first end 131 cannot be entirely removed and part of the passivation layer 14 remains on the first end 131 of the through via structure 13 (region A as shown in FIGS. 1 and 2). As a result, the yield rate of the through via structure 13 and the redistribution layer 15 is reduced. In addition, since the first end 131 of the through via structure 13 is exposed on the first surface 111 of the silicon base material 11 but not on the surface 141 of the passivation layer 14, the process of the redistribution layer 15 is complicated.

Consequently, there is an existing need for a semiconductor process, a semiconductor element and package having the semiconductor element that solves the above-mentioned problems.

### SUMMARY OF THE INVENTION

The present invention provides a semiconductor process. The semiconductor process comprises the steps of: (a) providing a semiconductor element including a silicon base material and at least one conductive via structure disposed in the silicon base material; (b) removing part of the silicon base material to form a first surface, wherein the conductive via structure protrudes from the first surface of the silicon base material so as to form a through via structure; (c) forming a protective layer on the first surface of the silicon base material to cover the through via structure, wherein the protective layer is made of photo-sensitive material; (d) removing part of the protective layer to form a first surface, so as to expose the through via structure on the first surface of the protective layer.

The present invention further provides a semiconductor element. The semiconductor element comprises a silicon base material, a protective layer, made of photo-sensitive material, and at least one through via structure. The silicon base material has a first surface and at least one groove. The groove opens at the first surface of the silicon base material. The protective layer is disposed on the first surface of the silicon base material and comprises a first surface and at least one through hole, wherein the through hole penetrates through the protective layer. The through via structure is disposed in the groove of the silicon base material and the through hole of the protective layer, and protrudes from the first surface of the protective layer.

The present invention further provides a package having a semiconductor element. The package comprises a substrate, a semiconductor element, a chip and a protective material. The semiconductor element is disposed on and electrically connected to the substrate. The semiconductor element comprises a silicon base material, a protective layer made of photo-sensitive material, and at least one through via structure. The silicon base material has a first surface and at least one groove. The groove opens at the first surface of the silicon base material. The protective layer is disposed on the first surface of the silicon base material and comprises a first surface and at least one through hole, wherein the through hole penetrates through the protective layer. The through via structure is disposed in the groove of the silicon base material and the through hole of the protective layer, and protrudes from the first surface of the protective layer. The chip is disposed on and electrically connected to the semiconductor element. The protective material is disposed on the substrate and encapsulating the semiconductor element and the chip.

Whereby, the through via structure protrudes from the first surface of the protective layer, and can be electrically connected to external elements directly, so that a step of forming a redistribution layer is omitted, and the semiconductor process is simplified.

### BRIEF DESCRIPTION OF THE DRAWINGS

FIG. 1 shows a cross-sectional view of a conventional semiconductor element;

FIG. 2 shows a partial enlarged view of FIG. 1;

FIGS. 3-10 show the schematic views of the semiconductor process of the present invention;

FIG. 11 shows a cross-sectional view of a semiconductor element according to a second embodiment of the present invention;

FIG. 12 shows a cross-sectional view of a semiconductor element according to a third embodiment of the present invention; and

FIG. 13 shows a cross-sectional view of a package having a semiconductor element of the present invention.

### DETAILED DESCRIPTION OF THE INVENTION

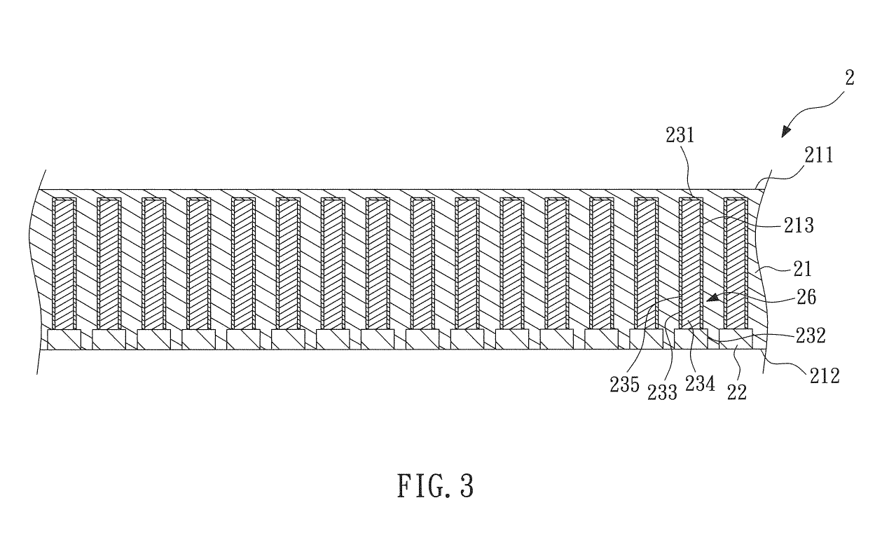

FIGS. 3-10 show the schematic views of the semiconductor process of the present invention. As shown in FIG. 3, a semiconductor element 2 is provided. The semiconductor element 2 includes a silicon base material 21 and at least one conductive via structure 26. In this embodiment, the semiconductor element 2 is a wafer and further includes at least one electrical device 22. The silicon base material 21 has a top surface 211, a second surface 212 and at least one groove 213. The electrical device 22 is disposed in the silicon base material 21 and exposed on the second surface 212 of the silicon base material 21. In this embodiment, the electrical device 22 is a complementary metal-oxide-semiconductor (CMOS).

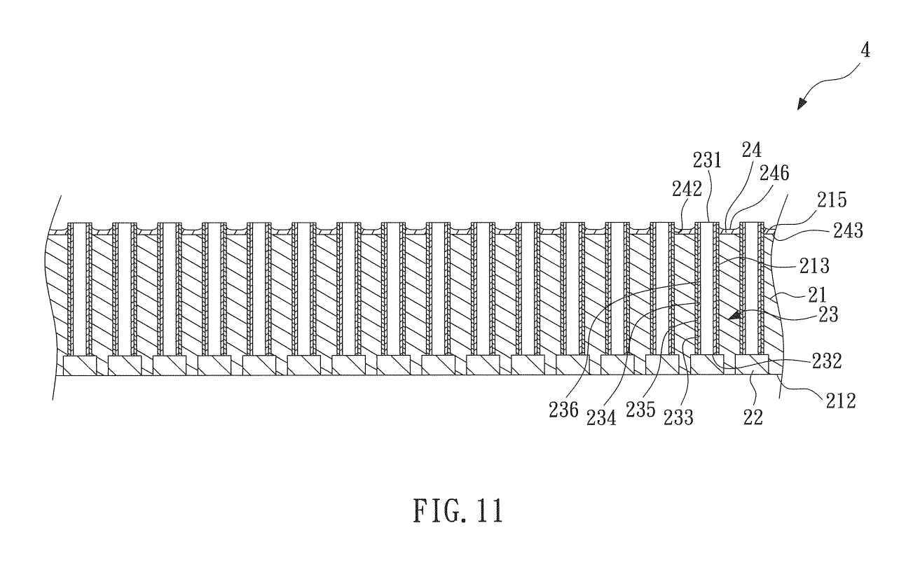

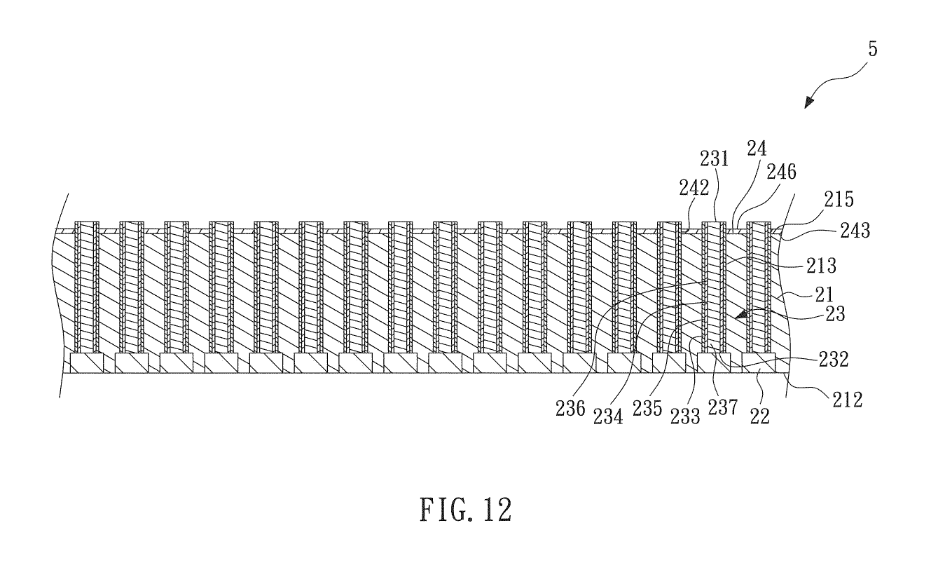

The conductive via structure 26 is disposed in the groove 213 and has a first end 231 and a second end 232. The second end 232 is connected to the electrical device 22, and the conductive via structure 26 does not penetrate through the silicon base material 21; that is, the first end 231 of the conductive via structure 26 does not be exposed on or protrude from the top surface 211 of the silicon base material 21. In this embodiment, the conductive via structure 26 comprises an outer insulation layer 233 and a conductor 234. The outer insulation layer 233 is disposed on the side wall of the groove 213 and covered the first end 231 of the conductive via structure 26 to define a second central groove 235, and the second central groove 235 is filled with the conductor 234. The conductor 234 of the conductive via structure 26 is made of copper. However, in other embodiments, the second central groove 235 is not filled with the conductor 234, and the conductor 234 is disposed on the side wall of the second central groove 235 to define a first central groove 236 (as shown in FIG. 11). Alternatively, the conductive via structure 26 can further comprise an inner insulation layer 237 (as shown in FIG. 12) with which the first central groove 236 is filled.

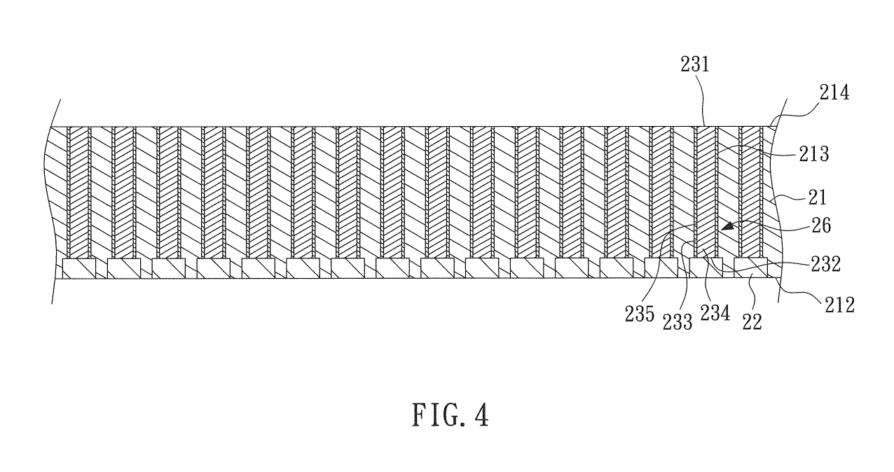

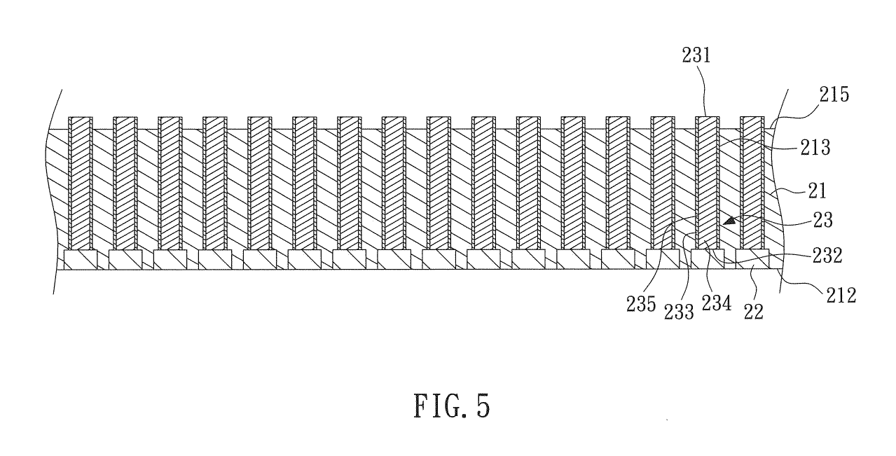

As shown in FIG. 4, part of the silicon base material 21 is removed from the top surface 211 (FIG. 3) by grinding so as to form a third surface 214. The first end 231 of the conductive via structure 26 is exposed on the third surface 214. As shown in FIG. 5, part of the silicon base material 21 is removed to form a first surface 215. The groove 213 opens at the first surface 215, the conductive via structure 26 protrudes from the first surface 215 of the silicon base material 21, to form a through via structure 23. In this embodiment, part of the silicon base material 21 is removed from the third surface 214 by etching (FIG. 4), so as to form the first surface 215. The first end 231 of the conductive via structure 26 protrudes from the first surface 215 of the silicon base material 21 so as to form the through via structure 23.

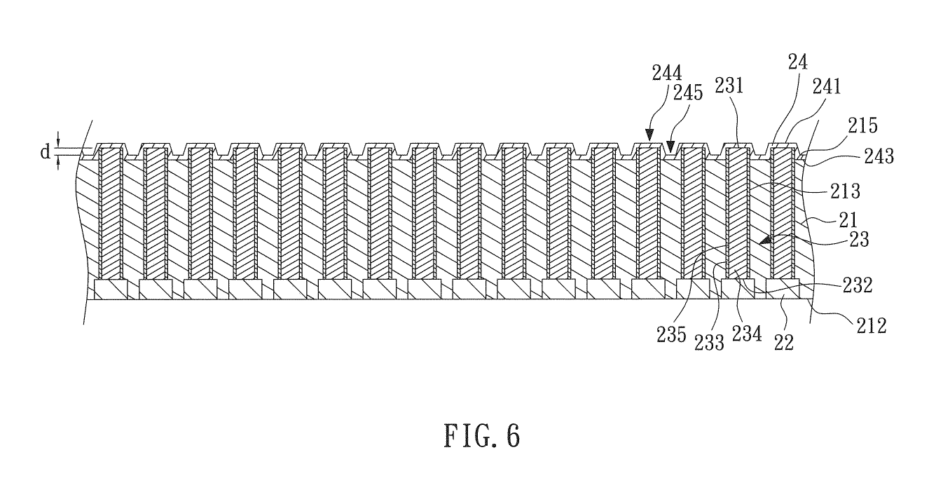

As shown in FIG. 6, a protective layer 24 is disposed on the first surface 215 of the silicon base material 21, to cover the first end 231 of the through via structure 23. The protective layer 24 has a top surface 241 and a second surface 243, and is made of photo-sensitive material. In this embodiment, the protective layer 24 is a positive-photoresist, for example, polybenzoxazole (PBO), and is formed by spin coating or spray coating. In other embodiments, the protective layer 24 can be a negative-photoresist, for example, benzocyclobutance (BCB). Preferably, the protective layer 24 comprises a first portion 244 and a second portion 245. The first portion 244 covers the through via structure 23; in the next step, the first portion 244 is removed so as to expose the through via structure 23. The second portion 245 of the protective layer 24 covers the first surface 215 of the silicon base material 21 and is disposed adjacent to the through via structure 244; in the next step, part of the second portion 245 remains, and a horizontal level of the top portion of the second portion 245 is lower than that (the first end 231) of the top portion of the through via structure 23, so that there exists a distance d between the top portion of the second portion 245 and the top portion (the first end 231) of the through via structure 23.

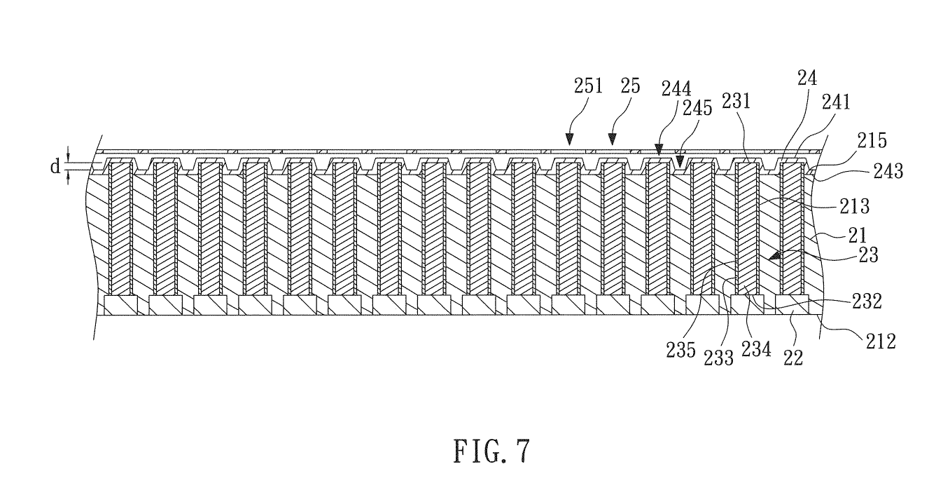

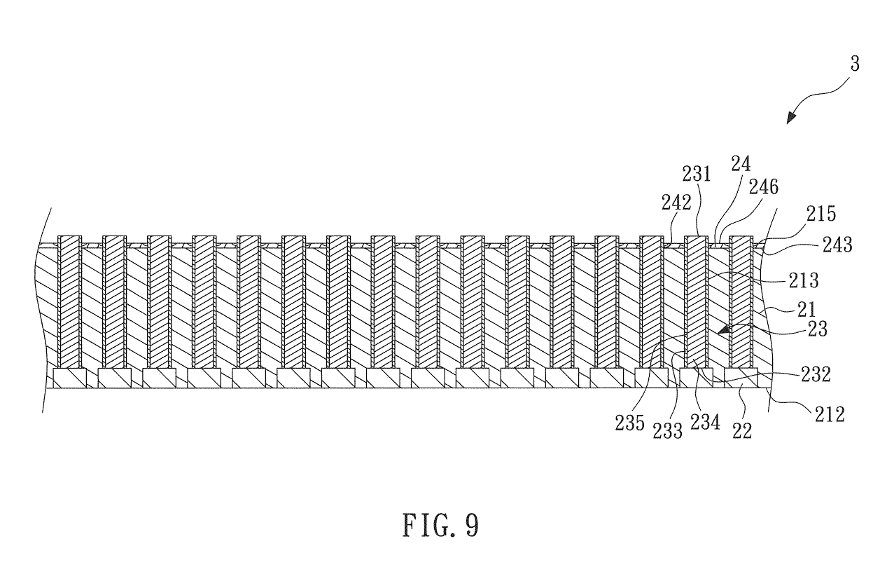

As shown in FIG. 7, a photomask 25 having at least one opening 251 is provided above the protective layer 24, to cover part of the protective layer 24. In this embodiment, the position of the opening 251 corresponds to the first portion 244 of the protective layer 24. In this embodiment, the protective layer 24 is a positive-photoresist, and after the first portion 244 of the protective layer 24 is irradiated by a light source (not shown), the molecular bond is broken. A dissolving rate of the first portion 244 of the protective layer 24 in an aqueous base developer, for example, tetramethylammonium hydroxide (TMAH) is faster than that of the second portion 245 of the protective layer 24. Therefore, after a process of development, the second portion 245 of the protective layer 24 will be reserved on the first surface 215 of the silicon base material 21 (as shown in FIG. 9).

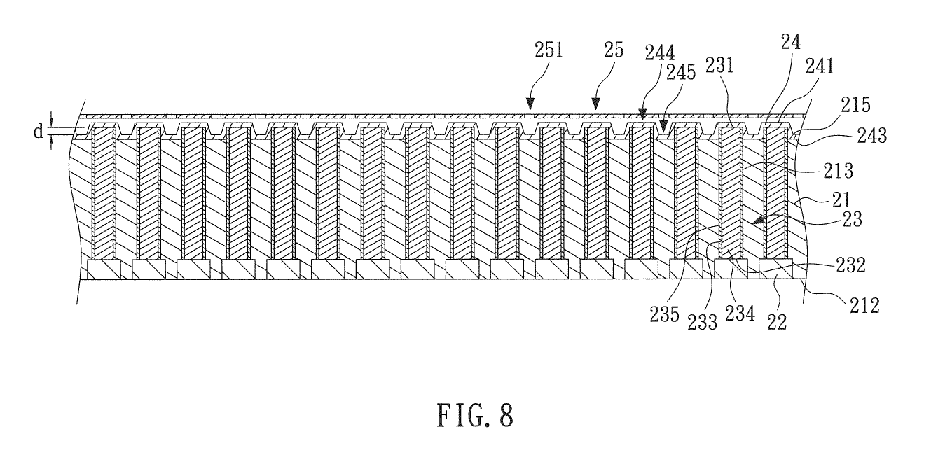

However, in other embodiments, the protective layer 24 is a negative-photoresist, as shown in FIG. 8, the exposed region of the protective layer 24 is hardened due to the cross-linking reaction. The position of the opening 251 of the photomask 25 corresponds to the second portion 245 of the protective layer 24. After an exposure process, the second portion 245 of the protective layer 24 is irradiated by a light source (not shown), a dissolving rate of the second portion 245 of the protective layer 24 in an aqueous base developer, for example, tetramethylammonium hydroxide (TMAH) is slower than that of the first portion 244 of the protective layer 24. Therefore, after a process of development, the second portion 245 of the protective layer 24 will be reserved on the first surface 215 of the silicon base material 21.

Preferably, in other embodiments, the exposure process can be omitted no matter the protective layer 24 is a positive type or a negative type photoresist. Since the protective layer 24 is formed by spin coating or spray coating, the thickness of the first portion 244 of the protective layer 24 is thinner than that of the second portion 245 of the protective layer 24. After the protective layer 24 is disposed on the first surface 215 of the silicon base material 21, a development process proceeds with an aqueous base developer, for example, tetramethylammonium hydroxide (TMAH), and it will result in a residual at second portion 245 of the protective layer 24.

As shown in FIG. 9, part of the protective layer 24 (the first portion 244) is removed, so as to form a first surface 246 and at least one through hole 242, and a semiconductor element 3 according to a first embodiment of the present invention is manufactured. The through hole 242 penetrates through the first surface 246 and the second surface 243 of the protective layer 24. The through via structure 23 is disposed in the through hole 242 of the protective layer 24 and exposed on the first surface 246 of the protective layer 24. Preferably, the first end 231 of the through via structure 23 protrudes from the first surface 246 of the protective layer 24 and is spaced apart from the first surface 246 over 1 μm, i.e., the first end 231 of the through via structure 23 protrudes from the first surface 246 over 1 μm.

By utilizing the characteristics of the chemical reaction of the protective layer 24 (which is made of photo-sensitive material) after being irradiated by a light source, part of the protective layer 24 on the through via structure 23 can be entirely removed, so that the yield rate of electrically connecting the through via structure 23 and external elements is ensured.

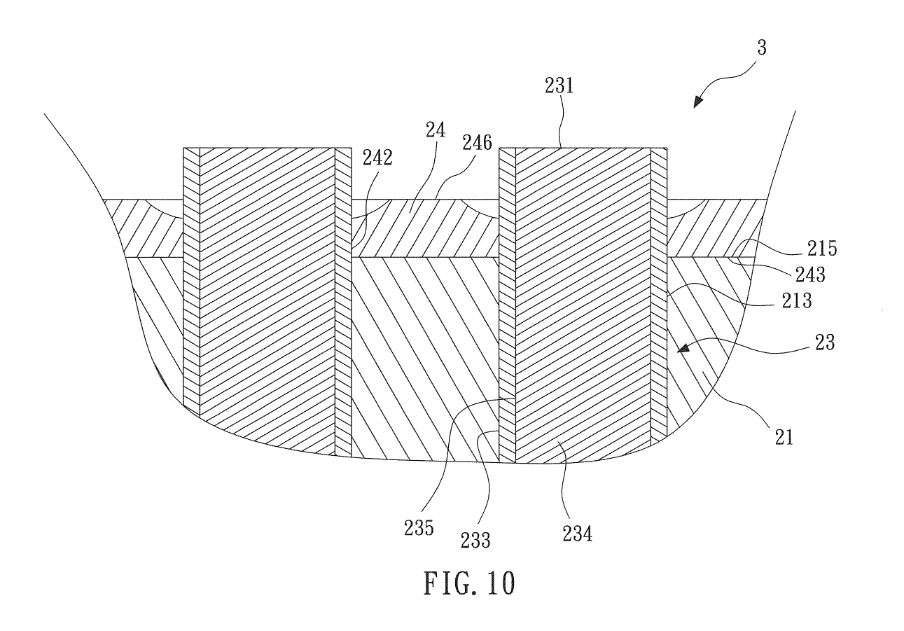

Referring to FIGS. 9 and 10, a cross-sectional view of the semiconductor element according to the first embodiment of the present invention and its partial enlarged view are shown. The semiconductor element 3 comprises a silicon base material 21 and at least one through via structure 23. In this embodiment, the silicon base material 21 is a wafer and comprises at least one electrical device 22 and a protective layer 24. The silicon base material 21 has a first surface 215, a second surface 212 and at least one groove 213. The groove 213 opens at the first surface 215. The electrical device 22 is disposed in the silicon base material 21 and exposed on the second surface 212 of the silicon base material 21. In this embodiment, the electrical device 22 is a complementary metal-oxide-semiconductor (CMOS).

The protective layer 24 is disposed on the first surface 215 of the silicon base material 21. The protective layer 24 has a first surface 246, a second surface 243 and at least one through hole 242. The through hole 242 penetrates through the first surface 246 and the second surface 243. In this embodiment, the thickness of the protective layer 24 is not uniform, wherein partial protective layer 24 around the through via structure 23 is less than that of the remainder of the protective layer 24.

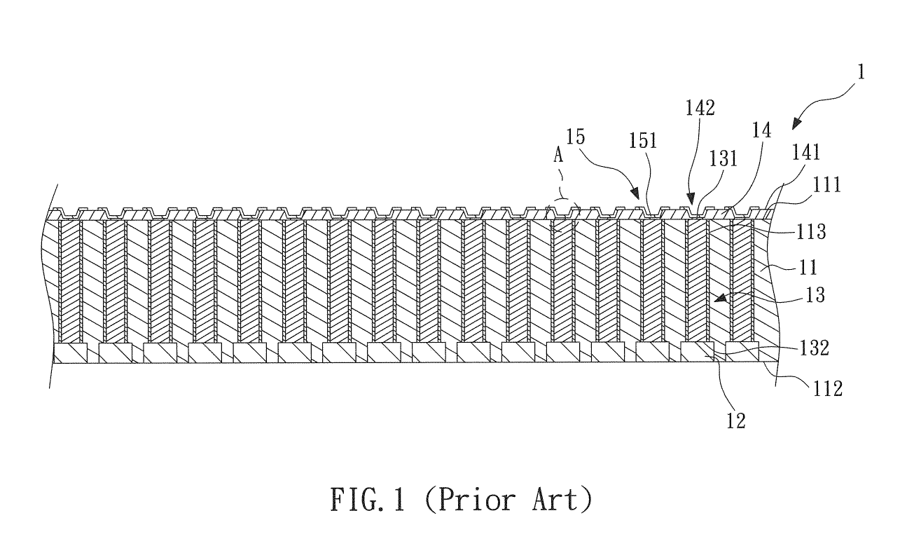

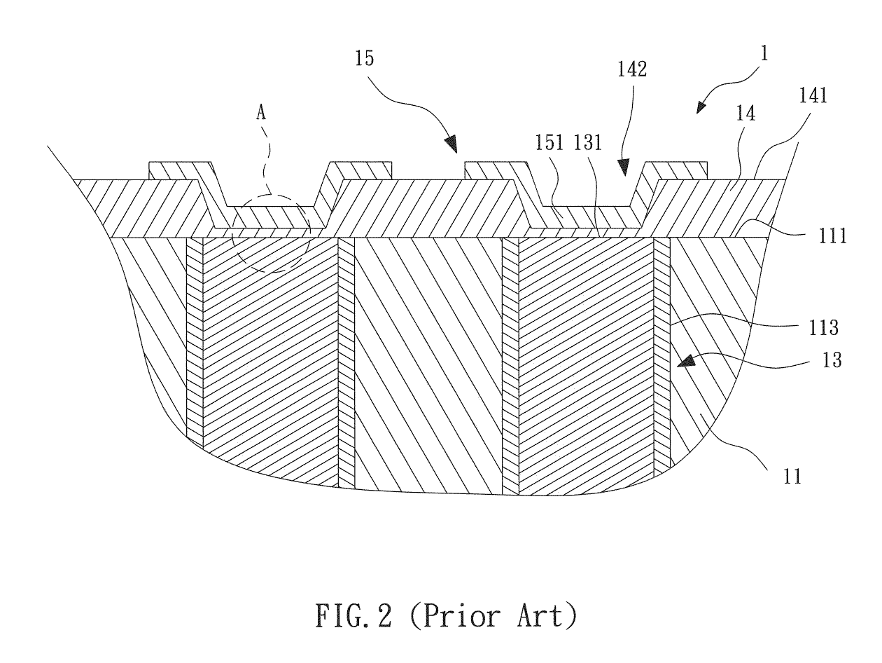

The through via structure 23 is disposed in the groove 213 and the through hole 242, and protrudes from the first surface 246 of the protective layer 24. The through via structure 23 has a first end 231 and a second end 232, wherein the first end 231 protrudes from the surface 246 of the protective layer 24, and the second end 232 is connected to the electrical device 22. In this embodiment, the through via structure 23 comprises an outer insulation layer 233 and a conductor 234. The outer insulation layer 233 is disposed on the side wall of the groove 213 to define a second central groove 235, and the second central groove 235 is filled with the conductor 234. The conductor 234 of the through via structure 23 is made of copper.

Whereby, the through via structure 23 protrudes from the first surface 246 of the protective layer 24, so it can be electrically connected to external elements directly, so that a step of forming a redistribution layer 15 (FIG. 1) is omitted, and the semiconductor process is simplified.

FIG. 11 shows a cross-sectional view of a semiconductor element according to a second embodiment of the present invention. The semiconductor element 4 of the second embodiment and the semiconductor element 3 (FIG. 9) of the first embodiment are substantially the same, and the same elements are designated with the same numerals. The difference between the second embodiment and the first embodiment is that the second central groove 235 is not filled with the conductor 234, and the conductor 234 is disposed on the side wall of the second central groove 235 to define a first central groove 236. In addition, the thickness of the protective layer 24 is not uniform, and the thickness of partial protective layer 24 around the through via structure 23 is greater than that of the remainder of the protective layer 24.

FIG. 12 shows a cross-sectional view of a semiconductor element according to a third embodiment of the present invention. The semiconductor element 5 of the third embodiment and the semiconductor element 4 (FIG. 11) of the second embodiment are substantially the same, and the same elements are designated with the same numerals. The difference between the third embodiment and the second embodiment is that the through via structure 23 can further comprise an inner insulation layer 237 with which the first central groove 237 is filled. In addition, the protective layer 24 has an substantially uniform thickness, and the thickness of partial protective layer 24 around the through via structure 23 is the same as that of the remainder of the protective layer 24.

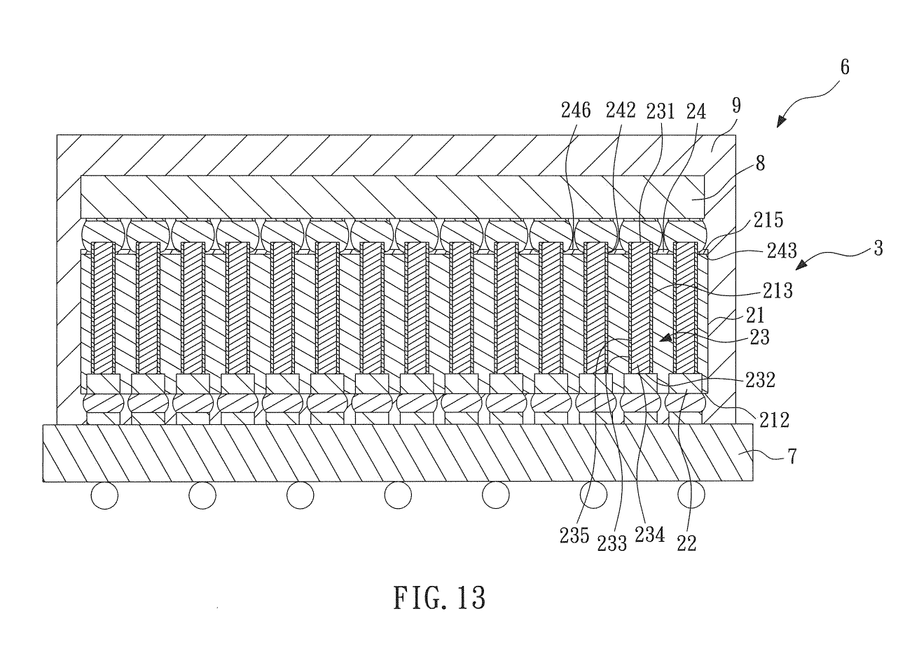

FIG. 13 shows a cross-sectional view of a package having a semiconductor element of the present invention. As shown in FIG. 13, the package 6 comprises a substrate 7, a semiconductor element, a chip 8 and a protective material 9. The semiconductor element is disposed on and electrically connected to the substrate 7. In this embodiment, the semiconductor element is the semiconductor element 3 according to the first embodiment of the present invention. It should be noted that in other embodiments, the semiconductor element can be the semiconductor element 4 according to the second embodiment or the semiconductor element 5 according to the third embodiment of the present invention. The chip 8 is disposed on and electrically connected to the semiconductor element. The protective material 9 is disposed on the substrate 7 and encapsulates the semiconductor element and the chip 8.

While embodiments of the present invention have been illustrated and described, various modifications and improvements can be made by those skilled in the art. The embodiments of the present invention are therefore described in an illustrative but not restrictive sense. It is intended that the present invention is not limited to the particular forms illustrated, and that all modifications that maintain the spirit and scope of the present invention are within the scope defined in the appended claims.

1. A semiconductor process, comprising the steps of:
(a) providing a semiconductor element including a silicon base material and at least one conductive via structure disposed in the silicon base material;
(b) removing part of the silicon base material to form a first surface, wherein the conductive via structure protrudes from the first surface of the silicon base material so as to form a through via structure;
(c) forming a protective layer on the first surface of the silicon base material to cover the through via structure, wherein the protective layer is made of photo-sensitive material;
(d) removing part of the protective layer to form a first surface, so as to expose the through via structure on the first surface of the protective layer.

2. The semiconductor process according to claim 1, wherein in step (a), the silicon base material comprises at least one groove, and the conductive via structure is disposed in the groove.

3. The semiconductor process according to claim 1, wherein the silicon base material comprises a top surface; before step (b), part of the silicon base material is removed from the top surface to form a third surface, wherein the conductive via structure is exposed on the third surface; and in step (b), part of the silicon base material is removed from the third surface to form the first surface.

4. The semiconductor process according to claim 1, wherein in step (c), the protective layer comprises a first portion and a second portion, the first portion covers the through via structure, the second portion is disposed adjacent to the through via structure, and a thickness of the first portion is thinner than that of the second portion.

5. The semiconductor process according to claim 1, further comprising the following steps in step (d):
(d1) providing a photomask above the protective layer to cover part of the protective layer;
(d2) providing a light source to irradiate the uncovered protective layer; and
(d3) removing part of the protective layer by using a developer solution.

6. The semiconductor process according to claim 5, wherein in step (c), the material of the protective layer is a positive-photoresist; in step (d1), the photomask covers the second portion of the protective layer and exposes the first portion of the protective layer; in step (d2), after the first portion of the protective layer is irradiated by the light source, the molecular bond is broken; in step (d3), the developer solution is used to remove the first portion of the protective layer.

7. The semiconductor process according to claim 5, wherein in step (c), the material of the protective layer is a negative-photoresist; in step (d1), the photomask covers the first portion of the protective layer and exposes the second portion of the protective layer; in step (d2), after the second portion of the protective layer is irradiated by the light source, the protective layer is hardened due to the cross-linking reaction caused by the irradiation; in step (d3), a developer solution is used to remove the first portion of the protective layer.

8. The semiconductor process according to claim 1, wherein in step (d), the protective layer further comprises at least one through hole, the through hole penetrates through the protective layer, and the through via structure is disposed in the through hole of the protective layer.

9. The semiconductor process according to claim 1, wherein in step (d), the through via structure protrudes from the first surface of the protective layer.

10. The semiconductor process according to claim 9, wherein in step (d), the through via structure comprises a first end, the first end protrudes from the first surface of the protective layer and is spaced apart from the first surface over 1 μm.

11. A semiconductor element, comprising:
a silicon base material, having a first surface and at least one groove, and the groove opening at the first surface of the silicon base material;
a protective layer, made of photo-sensitive material, disposed on the first surface of the silicon base material, and comprising a first surface and at least one through hole, wherein the through hole penetrates through the protective layer; and
at least one through via structure, disposed in the groove of the silicon base material and the through hole of the protective layer, and protruding from the first surface of the protective layer.

12. The semiconductor element according to claim 11, wherein the through via structure comprises an outer insulation layer and a conductor, the outer insulation layer is disposed on the side wall of the groove to define a second central groove, and the conductor is disposed on the side wall of the second central groove.

13. The semiconductor element according to claim 11, wherein the through via structure comprises an outer insulation layer and a conductor, the outer insulation layer is disposed on the side wall of the groove to define a second central groove, and the second central groove is filled with the conductor.

14. The semiconductor element according to claim 11, wherein the through via structure comprises an outer insulation layer, a conductor and an inner insulation layer, the outer insulation layer is disposed on the side wall of the groove to define a second central groove, the conductor is disposed on the side wall of the second central groove to define a first central groove, and the first central groove is filled with the inner insulation layer.

15. The semiconductor element according to claim 11, wherein the through via structure comprises a first end, the first end protrudes from the first surface of the protective layer and is spaced apart from the first surface over 1 μm.

16. A package having a semiconductor element, comprising:
a substrate;
a semiconductor element, disposed on and electrically connected to the substrate, the semiconductor element comprising:
a silicon base material, having a first surface and at least one groove, and the groove opening at the first surface of the silicon base material;
a protective layer, made of photo-sensitive material, disposed on the first surface of the silicon base material, and comprising a first surface and at least one through hole, wherein the through hole penetrates through the protective layer; and
at least one through via structure, disposed in the groove of the silicon base material and the through hole of the protective layer, and protruding from the first surface of the protective layer;
a chip, disposed on and electrically connected to the semiconductor element; and
a protective material, disposed on the substrate and encapsulating the semiconductor element and the chip.

17. The package according to claim 16, wherein the protective layer is made of photo sensitive polybenzoxazole (PBO) or photo sensitive benzocyclobutance (BCB).

18. The package according to claim 16, wherein the through via structure comprises an outer insulation layer and a conductor, the outer insulation layer is disposed on the side wall of the groove to define a second central groove, and the second central groove is filled with the conductor.

19. The package according to claim 16, wherein the through via structure comprises an outer insulation layer, a conductor and an inner insulation layer, the outer insulation layer is disposed on the side wall of the groove to define a second central groove, the conductor is disposed on the side wall of the second central groove to define a first central groove, and the first central groove is filled with the inner insulation layer.

20. The semiconductor element according to claim 16, wherein the through via structure comprises a first end, the first end protrudes from the first surface of the protective layer and is spaced apart from the first surface over 1 μm.

21. A semiconductor process, comprising the steps of:
(a) providing a semiconductor element including a silicon base material and at least one conductive via structure embedded in the silicon base material, wherein the conductive via structure comprises an outer insulation layer and a conductor having a top surface;
(b) removing part of the silicon base material and a portion of the outer insulation layer to form a third surface and to expose the top surface of the conductor;
(c) removing part of the silicon base material between the top surfaces of the conductors from the third surface to form a first surface, wherein the conductive via structure protrudes from the first surface of the silicon base material, so as to form a through via structure.

22. The semiconductor process according to claim 21, wherein in step (a), the conductor further comprises a side surface, and the outer insulation layer covers the top surface and the side surface of the conductor.

23. The semiconductor process according to claim 21, further comprising a step (d):
(d) forming a protective layer on the first surface of the silicon base material.

24. The semiconductor process according to claim 21, wherein in step (c), part of the silicon base material between the top surfaces of the conductors is removed from the third surface by etching.
